(19) United States
(12) Patent Application Publication
(10) Pub. No.: US 2014/0026936 A1
(43) Pub. Date: Jan. 30, 2014

(54) PHOTOVOLTAIC SOLAR CELL AND A METHOD FOR THE PRODUCTION OF SAME

(71) Applicants: Benjamin Thaidigsmann, Freiburg (DE); Florian Clement, Freiburg (DE); Andreas Wolf, Freiburg (DE); Daniel Biro, Freiburg (DE)

(72) Inventors: Benjamin Thaidigsmann, Freiburg (DE); Florian Clement, Freiburg (DE); Andreas Wolf, Freiburg (DE); Daniel Biro, Freiburg (DE)

(73) Assignee: Fraunhofer-Gesellschaft Zur Forderung Der Angewand ten Forschung E.V., Munchen (DE)

(21) Appl. No.: 13/982,894

(22) PCT Filed: Jan. 26, 2012
(86) PCT No.: PCT/EP2012/051243

§ 371 Date: Oct. 16, 2013

(30) Foreign Application Priority Data
Feb. 1, 2011 (DE) 10 2011 010 077.6

(51) Int. Cl. H01L 31/0224

(52) U.S. Cl. CPC H01L 31/02245
USPC 136/244; 136/256; 438/98

(57) ABSTRACT

A photovoltaic solar cell for converting incident electromagnetic radiation into electrical energy, including at least one base region of a base-doping type, designed in a silicon substrate; at least one emitter region of an emitter-doping type that is of an opposite doping type to the base-doping type; at least one metallic base-contacting structure connected, in an electrically conductive manner, to the base region, and at least one metallic emitter-contacting structure connected, in an electrically conductive manner, to the emitter region, the base region and emitter region being arranged in such a manner that a pn-junction is formed at least in some regions between said base and emitter regions. It is essential that the base-contacting structure overlaps the emitter region in a base-bypass region and that in said overlapping region, a diode-like semiconductor contact is designed between the base-contacting structure and the emitter region, said semiconductor contact being a metal semiconductor contact or as a metal-insulator-semiconductor contact, and/or that the emitter-contacting structure overlaps the base region in an emitter-bypass region and that in this overlapping region, a diode-like semiconductor contact is designed between the emitter-contacting structure and the base region, said semiconductor contact being a metal semiconductor contact or as a metal-insulator-semiconductor contact. The invention also relates to a method for producing a solar cell.

### BACKGROUND

The invention relates to a photovoltaic solar cell for converting incident electromagnetic radiation into electric energy as well as a method for its production.

A photovoltaic solar cell represents a planar semiconductor component in which pairs of charge carriers are generated via incident electromagnetic radiation and subsequently they are separated so that a potential develops between at least two metallic contacting structures of the solar cell and via an external circuit connected to said contacting structures electric power can be tapped from said solar cell. The separation of the charge carriers occurs at a pn-junction, which for example can be realized such that in a silicon substrate of one base doping type a doping is performed of a doping type opposite thereto in order to form an emitter. It is also known to form the emitter by applying one or more layers on a base substrate.

The present invention relates to a solar cell and a method for its production with at least the base being embodied in a silicon substrate, thus the solar cell represents a silicon solar cell.

In order to convert incident electromagnetic radiation into electric energy modules are used which comprise a plurality of photovoltaic solar cells. During the installation in a photovoltaic module, the solar cells are combined serially to so-called strings. A module usually comprises several strings. The operation of such a module can lead to the following problems:

Under certain circumstances, during the operation of a module some of the solar cells included are shadowed, for example by leaves or other objects located between the light source (typically the sun) and the solar cell. The electric current generated by a solar cell depends on the luminosity impinging the respective solar cell. When now some of the solar cells, which are switched serially in a string, is shadowed partially or entirely the polarity of said shadowed solar cells can be reversed because the generated electric current of these solar cells is lower than the one of the completely illuminated solar cells.

In this case the shadowed solar cells are operated in the reverse direction, i.e. a voltage is applied at the metallic contacts of these solar cells, which exhibits a reverse polarity compared to the voltage applied to the metallic contacts of the solar cells not shadowed. The electric current of the entire string comprising the solar cells partially or entirely shadowed and thus the electric power generated by these strings is largely reduced by this shadowing.

Here and in the following negative voltage or voltage applied in the reverse direction is called the state, as is common, in which at the metallic contacts of a solar cell a voltage and/or an electric current is given opposite the voltage and/or the electric current flow during normal operation. The voltage and the electric current during normal operation (particularly not shadowed) is called positive voltage or voltage in the forward direction, as is common.

Depending on the design of the module and the type of shadowing the negative voltage applied at the shadowed solar cell can become very high and may lead to an uncontrolled breakdown in the reverse direction at the shadowed solar cell or cells. Here, electric energy is converted into heat inside the solar cells operating in the reverse direction. This may lead to damages in the module. Such damages typically occur when the electric current flowing in the reverse direction is not flowing planar over the entire area of the solar cell or at least a large portion of said solar cell but only over localized sections of the solar cell, which accordingly show a high electric current and strongly heat up (so-called hot spots). Particularly at such hot spots the solar cell and/or the module can be destroyed by the development of intense heat.

Therefore, during the production of solar cell modules usually bypass diodes are provided, which are switched electrically parallel in reference to the strings. The bypass diodes limit the maximum voltage in the reverse direction to the overall voltage of a respective string. The smaller the number of cells in a string the lower the maximum voltage which may be applied to shadowed solar cells in the reverse direction so that the risk of a breakdown and thus also a reduction of power is reduced during partial shadowing.

In order to yield high effectiveness of the modules even in case of a partial shadowing of the module it would therefore be optimal to switch one bypass diode electrically parallel to each solar cell so that in the module theoretically a string size of one solar cell is given. Due to the high production expense and the corresponding high production costs this is not practicable, though.

Accordingly it is known to provide diodes inside the solar cells as independent electronic components and to switch respectively the positive and negative metallic contacts of the solar cell via these bypass diodes. Such solar cells are described in U.S. Pat. No. 5,616,185 and WO 2010/029180 A1. Here it is disadvantageous that during the production of these solar cells considerable additional processing steps are required, particularly diffusion steps for the production of the bypass diode in a semiconductor substrate of the solar cell. Accordingly considerably higher production costs develop for such solar cells.

### SUMMARY

The present invention is therefore based on the objective of providing a photovoltaic solar cell and a method for its production in order to implement the functionality of a bypass diode inherently in a solar cell without here causing considerably increased production complexity during the manufacturing and thus higher production costs.

This objective is attained in a photovoltaic solar cell and a method for the production of a photovoltaic solar cell according to the invention. Preferred embodiments of the solar cell according to the invention are disclosed below; preferred embodiments of the method according to the invention are also disclosed below. Here, the wording of the claims is explicitly included in the description by way of reference.

The photovoltaic solar cell according to the invention is designed to convert incident electromagnetic radiation into electric energy. The solar cell comprises at least one base region of a base doping type and at least one emitter region of an emitter doping type. The emitter doping type is opposite the base doping type. The doping types are here the n-doping and the p-doping opposite thereto.

Furthermore, the solar cell comprises at least one metallic base contacting structure, which base contacting structure is connected in an electrically conducting fashion to the base region and a metallic emitter contacting structure, which emitter contacting structure is connected to the emitter region in an electrically conducting fashion.

The base region and the emitter region are here arranged such that a pn-junction forms at least sectionally between the base region and the emitter region.

The scope of the invention includes that the emitter region in the silicon substrate is particularly formed by way of diffusion. The embodiment of the emitter as a layer arranged at the silicon substrate, perhaps with additional interim layers being interposed, is also within the scope of the invention. Furthermore the embodiment of the pn-junction as a pin-junction is also within the scope of the invention, i.e. with an intrinsic doped layer being interposed.

The emitter and the base contacting structure may here be arranged at the front and/or the rear of the solar cell. The scope of the invention particularly includes arranging the base contacting structure on an opposite side or the same side as the emitter contacting structure.

It is essential that in the photovoltaic solar cell according to the invention the base contacting structure overlaps the emitter region in a base bypass region and in this overlapping region at least in a partial area, preferably in the entire overlapping region, a diode-like semiconductor contact is embodied between the base contacting structure and the emitter region. The semiconductor contact is embodied as a metal-semiconductor contract, preferably a Schottky-contact.

Alternatively or additionally the emitter contacting structure is embodied overlapping the base region in an emitter bypass region, and in this overlapping region at least in a partial area, preferably in the entire overlapping region, a diode-like semiconductor contact is embodied between the emitter contacting structure and the base region. The semiconductor contact is embodied as a metal-semiconductor contact, preferably a Schottky contact.

The photovoltaic solar cell according to the invention therefore comprises at least one overlapping region, in which overlapping region a diode-like semiconductor contact is formed. This semiconductor contact may be embodied between the base contacting structure and the emitter region or between the emitter contacting structure and the base region. It is also within the scope of the invention that the solar cell comprises several overlapping regions, in which one diode-like semiconductor contact each is embodied between the base contacting structure and the emitter region and/or between the emitter contacting structure and the base region.

The solar cell according to the invention therefore comprises at least one diode-like semiconductor contact, which connects a contacting structure via a diode-like electric contact to a dissimilar semiconductor region of the solar cell. Accordingly the functionality of a bypass diode is implemented by the diode-like semiconductor contacts, and unlike solar cells of prior art, here no separate diode is embodied, rather the diode-like contact is established between the metallic contacting structure and the emitter and/or base region of the solar cell.

The invention is based on the knowledge of the applicant that by embodying the above-mentioned diode-like semiconductor contacts in the overlapping regions the functionality of a bypass diode is yielded in a simple and cost-effective fashion. In particular, no installation of an additional bypass diode is required when the solar cell according to the invention is used in a module. Similarly, the expensive embodiment of a diode-like structure inside the solar cell via additional diffusions can be waived, here.

Accordingly, with the solar cell according to the invention a solar cell module can be produced, which exhibits increased efficiency by the bypass functionality of each individual solar cell in this module.

The method according to the invention for producing a photovoltaic solar cell comprises the following processing steps:

A silicon substrate is provided with a base region of one base doping type embodied in the silicon substrate.

An emitter region is embodied in or at the silicon substrate. The emitter region exhibits an emitter doping type, which is opposite the base doping type. The emitter region is embodied and/or arranged such that at least in partial areas a pn-junction forms between the base region and the emitter region.

A metallic base contacting structure is applied, which is connected to the base region in an electrically conducting fashion.

A metallic emitter contacting structure is applied, which is connected to the emitter in an electrically conducting fashion.

It is essential that the base contacting structure is applied in a base bypass region overlapping the emitter region and in this overlapping region at least in one partial area, preferably in the entire overlapping region, a diode-like metal-semiconductor contact is embodied, preferably a Schottky-contact, between the base contacting structure and the emitter region. Alternatively or additionally the emitter contacting structure is applied overlapping the base region in an emitter bypass region and in this overlapping region, at least in a partial area, preferably in the entire overlapping region, a diode-like metal semiconductor contact is formed, preferably a Schottky contact, between the emitter contacting structure and the base region.

The method according to the invention has the above-mentioned advantages that a solar cell is produced with the additional functionality of a bypass diode while only slightly increasing the processing complexity and thus raising production costs only to a minor extent.

The solar cell according to the invention is preferably embodied via the method according to the invention or a preferred embodiment thereof. The method according to the invention is preferably embodied for the production of a solar cell according to the invention or a preferred embodiment thereof.

The solar cell according to the invention can therefore be installed in a circuit in a solar cell module in a manner known per se, and here the need for the additional functionality of a bypass diode can be waived during the production of the module. Additionally, an external bypass diode can be omitted. If now during operation the situation mentioned at the outset occurs, for example a partial shadowing, so that one or more solar cells within a string are operated in the reverse direction i.e. that in these solar cells a voltage is applied in the reverse direction, then the diode-like semiconductor contact leads to a controlled breakdown in the overlapping region. This means that when a reverse voltage is applied, at least upon a certain voltage threshold being exceeded, a predetermined minimum electric current flows in the reverse direction via the diode-like semiconductor contact. This way, on the one side any development of excess voltage in the reverse direction is avoided and on the other side, by the controlled current flowing in the overlapping region at the diode-like semiconductor contact, the development of the above-mentioned hot-spots is also prevented.

Examinations of the applicant have shown that generally the above-mentioned negative effects, particularly by partial shadowing, are avoided when electric current flows in the reverse direction starting at a reverse voltage applied to a solar cell in an amount exceeding 5 V, preferably exceeding 3 Volt. Accordingly the solar cell is preferably embodied such that the diode-like semiconductor contact is embodied in an electrically conductive fashion in the reverse direction in the overlapping region, at least when a reverse voltage is applied at the metallic contact structures in an amount above 5 V, preferably in an amount above 3 V. Here and in the following the terms “electrically conducting” and “electrically blocking” are used in the manner common when describing diodes.

Examinations of the applicant have further shown that preferably within the above-stated limits for the reverse voltage at least one electric current is conducted in the blocking direction with an electric flow rate exceeding 100 mA/cm², preferably exceeding 500 mA/cm², further preferred exceeding 2000 mA/cm². Such an embodiment of the diode-like semiconductor contact ensures sufficient electric current flowing in the reverse direction, particularly in order to avoid hot-spots.

The electric currents stated here and in the following respectively relate to the area of the emitter and/or base bypass diode region, preferably the area of the respective overlapping region.

As described above, the diode-like semiconductor contact in the overlapping region leads to a controlled electric current flowing in the reverse direction when a reverse voltage is applied, at least when the amount of the reverse voltage exceeds a certain threshold. In the forward direction, i.e. during normal operation of a solar cell and accordingly with a voltage being applied in the forward direction at the metallic contacting structures of the solar cell, it is desired that in the overlapping region the diode-like semiconductor contact has no influence upon the solar cell characteristics or only to an irrelevant extent and particularly leads only to a minor reduction of effectiveness or none at all.

Preferably the diode-like semiconductor contact is embodied electrically blocking when a forward voltage is applied, i.e. in the normal operation of the solar cell, so that in the overlapping region no electric current flows in the forward direction between the base contacting structure and the emitter region and/or between the emitter contacting structure and the base region.

Examinations of the applicant have shown that in practice typically electric current flows when high voltages are applied in the forward direction, due to the embodiment of the semiconductor contact in the overlapping region. It is essential that in the voltage range relevant during the operation of the solar cell no or only minor electric current flows when a forward voltage is applied.

The solar cell according to the invention is therefore preferably embodied such that the diode-like semiconductor is embodied electrically blocking at a forward voltage applied at the metallic contact structures ranging from 0 V to 0.5 V, preferably from 0 V to 0.6 V. In particular, the diode-like semiconductor contact is preferably embodied such that within the above-mentioned voltage range electric currents flow below 10 mA/cm², preferably below 1 mA/cm², further preferred below 0.1 mA/cm².

In order to avoid any localized high temperature developing when electric current flows in the reverse direction at the overlapping regions and particularly to avoid the formation of hot-spots and a corresponding damage of the solar cell and/or the solar cell module it is advantageous that in the solar cell according to the invention one or more overlapping regions are embodied and the overall area of the overlapping region or regions is greater than 0.5%, preferably greater than 2%, further preferred greater than 5% of the overall area of the solar cell. Here, the term “overall area of the solar cell” relates to the common definition of the area of a solar cell, i.e. for example the area of the side facing the sun light during the operation of the solar cell.

The scope of the invention includes that in the overlapping region a metal-semiconductor contact is formed. Additionally, the scope of the invention includes that in the overlapping region additionally a metal-insulator semiconductor contact is formed.

Examinations of the applicant have shown that the embodiment of partial areas of the overlapping region as a metal-insulator semiconductor contact is advantageous because such a contact exhibits a better electric blocking effect when a forward voltage is applied.

Accordingly, in the solar cell according to the invention preferably in a partial area of the overlapping region a diode-like metal-insulator semiconductor contact is formed, in which an insulating layer is arranged between the metallic contacting structure and the semiconductor.

The insulating layer preferably covers more than 50%, further preferred more than 90% of the overlapping region.

Preferably the insulating layer exhibits a thickness of less than 500 nm, particularly less than 200 nm, preferably less than 150 nm. Furthermore it is advantageous that the insulation layer exhibits a thickness of more than 10 nm, preferably more than 50 nm. On the one hand these ranges of values for the thickness of the insulation layer lead to an optimization with regards to the electrically blocking effect when a voltage is applied in the forward direction and on the other hand to sufficient electric current flowing when a voltage is applied in the reverse direction, at least at a voltage with its amount exceeding the threshold voltage.

The insulation layer is preferably a silicon nitride layer, an aluminum nitride layer, or a silicon oxide layer. Additionally the scope of the invention also includes the use of a layer system between the semiconductor and the metallic contact structure.

Although no metal-semiconductor contact with a diode-like character can be produced by applying a metallic layer onto an electrically insulating layer, due to the electrically insulating effect, examinations of the applicant have shown, however, that in typical production methods the metallic layer penetrates the insulation layer sectionally, typically punctually. This can occur by so-called pin-holes, particularly in porous electrically insulating layers and/or by a punctual penetration of the metallic layer through the insulation layer to the semiconductor layer. In particular in the methods mentioned in the following, which include a “flash over” of the contacts, i.e. a temperature step in which a metal semiconductor contact is formed, in spite of the interposition of an insulation layer, a diode-like metal semiconductor contact can form, particularly at a thickness in the above-mentioned range.

Methods are known for producing and applying metallic contacting structures, in which metal pastes are used comprising frit, typically glass frit. The frit fulfills the function that when a contact is established, the so-called “contact flashing” i.e. the impingement of the metallic contacting structure with heat, the formation of an electric contact is promoted by the frit between the metallic contacting structure and the semiconductor. In particular it is possible that an insulating layer located between the contacting structure and the semiconductor is penetrated during contact flashing so that an electric contact is generated in spite of the presence of the insulating layer.

Examinations of the applicant have shown, however, that in the overlapping region any excessive rate of frit in the contacting structure is disadvantageous because during the contact flashing here a semiconductor contact develops which fails to exhibit the desired blocking effect described above when a voltage is applied in the reverse direction or exhibits it only to an insufficient extent.

Preferably, in the solar cell according to the invention, at least in the overlapping region, the metallic contact structure therefore comprises glass frit at a rate of less than 5%, preferably less than 2%, further preferred 1%. In particular it is advantageous that at least in the overlapping region the metallic contact structure comprises no glass frit at all.

As described above, in case it is embodied as a base contacting structure, the metallic contacting structure serves for electrically contacting the base region and in case it is embodied as an emitter contacting structure for electrically contacting the emitter region. It is therefore included in the scope of the invention that the metallic contacting structure is embodied uniformly, i.e. having a uniform composition both outside as well as inside the overlapping region.

The scope of the invention also includes embodying the base contacting structure with a composition different in the overlapping region. Additionally, the scope of the invention includes to embody the metallic contacting structure in several parts, for example, by a first part of the contacting structure with a first embodiment and particularly a first material composition being applied in the overlapping region and at least one second part of the contacting structure with a second embodiment and particularly a second material composition, which may be different from the first material composition, being formed in the areas in which an electric contacting of the base region shall occur. It is essential that the first and the second part of the contacting structure are connected to each other in an electrically conducting fashion. Preferably the first and the second part of the contacting structure are embodied directly abutting so that this way the electrically conducting connection is established between the two parts of the contacting structure.

Examinations of the applicant have further shown that it is disadvantageous for the desired functionality of a bypass diode in the overlapping region when the concentration of the doping substance at the surface or in the surface region of the semiconductor is excessively high in the overlapping region at the surface towards the metallic contacting structure. Here, high doping (i.e. a high p-doping or high n-doping) leads to a low blocking effect when a forward voltage is applied.

Preferably the solar cell according to the invention is therefore embodied such that in the overlapping region the doping concentration in the semiconductor at the surface towards the metallic contacting structure is below 10¹⁹ cm⁻³, preferably below 10¹⁸ cm⁻³, further preferred below 10¹⁷ cm⁻³.

The embodiment of a diode-like semiconductor contact as a metal-semiconductor contact and particularly a Schottky-contact is generally known to one trained in the art. Examinations of the applicant have shown that it is advantageous for the embodiment of a base bypass region and/or for the embodiment of an emitter bypass region to respectively use metals from a certain group, because the desired semiconductor contact can be easily formed from these metals.

In particular for embodying a Schottky-contact, it is known to one trained in the art that according to the theory of the Schottky-contact the electron affinity of the respective doping type at the surface of the semiconductor in the overlapping region and the electric affinity of the metal abutting the semiconductor surface in the overlapping region are essential for the features of the contact. Here, only the metal, which is directly contacting silicon, is decisive for the contacting features, with here any layer systems based thereon may be selected arbitrarily.

Accordingly it is advantageous that in the base bypass region the base contacting structure comprises one or more metals of the group silver, aluminum, titanium, palladium, zinc, platinum, nickel, tin, lead, cobalt, tungsten, and bismuth and/or that in the emitter bypass region the emitter contacting structure comprises one or more metals of the group silver, aluminum, titanium, palladium, zinc, platinum, nickel, tin, lead, cobalt, tungsten, and bismuth.

As described above, the solar cell according to the invention is characterized in the additional functionality of a bypass diode. This is ensured by the diode-like semiconductor contact in the overlapping region. The functionality of the bypass diode is yielded here such that when a voltage is applied in the forward direction the diode-like semiconductor contact is blocked electrically in the overlapping region, at least in the sense of the above-stated ranges for the voltage and with regards to the maximum electric current stated. Furthermore, the functionality of the bypass diode is characterized such that when a voltage is applied in the reverse direction, at least a voltage with a value exceeding the above-stated voltage limit, the diode-like semiconductor contact is electrically conducting in the overlapping region, at least with the above-stated electric currents. Here, it is irrelevant if with regards to electro-technical aspects the diode-like semiconductor contact is embodied in the overlapping region such that in the supplementary diagram a diode is arranged in the forward direction or in the reverse direction. It is essential here that the above-stated functionality of a bypass diode is ensured with the described minimum conditions with regards to the electric blocking and the electric conducting.

The scope of the invention includes that the diode-like semiconductor contact is embodied so that the supplementary diode diagram is arranged in the overlapping region such that, when a forward voltage is applied (i.e. in the typical operation of the solar cell), a voltage is applied in the blocking direction at the diode assumed in the supplementary diagram in the overlapping region and accordingly, when a partial shadowing is given and a reverse voltage is applied at the entire solar cell, a forward voltage is applied at the diode assumed in the supplementary diagram in the overlapping region.

However, the scope of the invention also includes that the diode-like semiconductor contact is embodied such that the assumed diode in the supplementary diagram is arranged inversely, i.e. that at this diode during normal operation a forward voltage is applied and upon partial shadowing a reverse voltage. Here it is essential that the diode parameter is embodied such that the above-mentioned minimum functionality of electric conducting and blocking is ensured.

In particular, the scope of the invention includes that in the overlapping region the diode-like metal-semiconductor contact is embodied with a forward voltage applied at the metallic contact structures at the diode positioned in the direction of flow (i.e. assumed diode in the supplementary diagram).

The surfaces of the semiconductor layers or the semiconductor substrate in solar cells frequently exhibit textures. This shall reduce reflections at the side of the solar cell facing the incident light during the operation of said solar cell so that a higher rate of the incident photons is coupled inside the solar cell. Additionally it is known to increase the internal reflection via textures such that any emission of photons already coupled in the solar cell out of the semiconductor substrate or the semiconductor layer is reduced. For this purpose, a multitude of textures is known, for example regular or irregular pyramidal structures.

Examinations of the applicant have shown that the embodiment of the diode-like semiconductor contact in the overlapping region is critical when uneven surfaces are given, particularly when textures are present. This is caused in that due to the uneven surfaces in individual local sections different electric conditions and/or layer arrangements may develop so that particularly the risk is given of an ohmic electric contact forming (unlike the desired diode-like semiconductor contact).

Preferably at least in the overlapping region the semiconductor surface of the solar cell according to the invention is here at least partially planar, preferably entirely planar. The wording “planar” relates here to the absence of textures, in particular showing an average surface finish with a coarseness of less than 5 μm.

The invention further relates to a solar cell module, which comprises one or more solar cells according to one of the previous claims. Here, the solar cells are electrically connected to each other in serial and/or parallel circuits in a manner known per se. In particular, the serial circuitry of solar cells in the form of strings and parallel circuitry of several such strings in a solar cell module are included in the scope of the invention.

Here it is possible to embody only one solar cell according to the invention in an overlapping region or some of the solar cells of the solar cell module, comprising at least one diode-like semiconductor contact. This way it is ensured, at least at the positions of said solar cells, that the functionality of a bypass diode is provided. For example the scope of the invention includes to form in a string of a solar cell module only some of the solar cells according to the invention and to distribute these solar cells in the above-mentioned string as evenly as possible, particularly only providing every other one, every third one, or every fourth solar cell according to the invention with the functionality of a bypass diode. Preferably all solar cells in the solar cell module according to the invention are embodied according to a solar cell according to the invention.

The solar cell module according to the invention preferably includes no external bypass diode, i.e. no bypass diode except for the integral diode-like semiconductor contact or contacts of the solar cell according to the present invention. This way the production costs are reduced during the manufacturing of the solar cell module.

Examinations of the applicant have shown that the embodiment of the diode-like semiconductor contact in the overlapping region is generally possible using the silicon-solar cell structures of prior art.

The embodiment of the method according to the invention for the production of a solar cell is particularly advantageous in such production methods in which the metallic contacting structure is applied via serigraphy. Advantageously, in the method according to the invention for the production of a solar cell accordingly, at least in the overlapping region, the contacting structure is applied via serigraphy, preferably by applying an argentiferous serigraphy paste. Examinations of the applicant have shown that in this form of producing the contacting structure a diode-like semiconductor contact can be produced in the overlapping region in a simple and inexpensive fashion.

The serigraphy paste in the above-mentioned preferred embodiment of the method beneficially comprises frit at a content ranging from 0.1% to 3%, preferably from 0.1% to 2%. This way it is ensured that on the one hand in a subsequent contact-flashing step the diode-like semiconductor contact is generated, on the other hand however the frit content is sufficiently low to prevent the generation of an ohmic electric contact in the overlapping region. In particular, it is advantageous that the serigraphy paste includes lead glass frit and/or zinc glass frit and/or bismuth glass frit. The content of lead glass frit is here preferably less than 1%.

Preferably the serigraphy paste includes one or more oxides, particularly one or more oxides from the group GeO₂, P₂O₅, Na₂O, K₂O, CaO, Al₂O₃, MgO, TiO₂, B₂O₃.

The embodiment of contacts, as described above, is preferably ensured by a contact-flashing step. In particular it is advantageous to subject the serigraphy paste, applied during the production of the solar cell, to a temperature ranging from 500° C. to 1000° C., preferably ranging from 700° C. to 900° C. The exposure to said temperature is preferably applied over a period from 1 s to 10 s. In particular the advantageous embodiment of the method according to the invention, in which the diode-like semiconductor contact in the overlapping region is generated in a serigraphy method known per se by applying a serigraphy paste, preferably an argentiferous serigraphy paste, shows that by only minor additional expenses the method according to the invention can be integrated into the production method already used in industrial production of solar cells. For example, when producing a solar cell with a diffused emitter only a portion of the surface of the solar cell needs to be spared during the emitter diffusion so that this spared section exhibits the base doping of the base doping type. During the application of the metallic emitter contacting structure, as known per se, the emitter is coated with serigraphy paste in the respective regions, additionally in this case also the previously spared sections are coated with serigraphy paste, i.e. regions in which the serigraphy paste is now provided on a semiconductor with a base doping of the base doping type.

In the subsequent contact-flashing step, on the one hand, in a manner known per se an electric contact is generated between the metallic emitter contacting structure and the diffused emitter. Simultaneously however, in the sections no emitter had been diffused, i.e. the overlapping region in the sense of the present invention, a diode-like semiconductor contact is generated ensuring the functionality of a bypass diode.

It is also possible that an emitter is first applied in a manner known per se and subsequently in the sections in which overlapping regions and accordingly diode-like semiconductor contacts shall be formed, the emitter is removed again, for example by re-etching the semiconductor.

The embodiment of the overlapping regions and the diode-like semiconductor contact in this overlapping regions is generally possible in typical solar cell structures known per se, particularly also in metal-wrap-through or MWT-solar cells, with their structure for example being described in U.S. Pat. No. 6,384,317 B1 or in the emitter-wrap-through or EWT-solar cells, with their structure being described for example in (“Emitter wrap-through solar cell”, Gee, 1993, DOI: 10.1109/PVSC. 1993.347173).

As described above, it is advantageous in the method according to the invention to apply the contacting structure via serigraphy at least in the overlapping region. Other methods for applying the contacting structure are also covered by the scope of the invention, particularly the application via non-contact printing methods, particularly inkjet or aerosol printing. The application of the contacting structure via physical gas phase precipitation is also included in the scope of the invention, preferably via evaporation.

The scope of the invention includes arranging the overlapping region in the solar cell according to the invention at the side of the solar cell facing the incident light during operation, at the side of the solar cell facing away, or several overlapping regions at both sides.

However, it is particularly advantageous to arrange the overlapping region at the rear, i.e. the side of the solar cell facing away from the incident light during the operation of the solar cell, because here for example a texturing is not mandatory, contrary to the front, and thus the overlapping region can be embodied in a planar fashion. Examinations of the applicant have shown that particularly the above-mentioned MWT-solar cell structure is suitable for embodying a solar cell according to the invention by generating overlapping regions at the rear emitter metallization with a diode-like embodied metal semiconductor contact. Here, particularly in such a MWT-solar cell, a solar cell according to the invention can be produced with the functionality of a bypass diode by a minor expansion of the processing steps during the production process.

### BRIEF DESCRIPTION OF THE DRAWINGS

Additional advantages and features of the present invention are explained in the following based on exemplary embodiments and the figures.

Shown are:

FIG. 1 the result of a current-voltage measurement at test structures with a diode-like semiconductor contact for different portions of lead oxide in the serigraphy paste;

FIG. 2 a schematic illustration of a detail of a first exemplary embodiment of a solar cell according to the invention;

FIG. 3 a schematic illustration of a detail of a second exemplary embodiment of a solar cell according to the invention;

FIG. 4 a schematic illustration of a detail of a third exemplary embodiment of a solar cell according to the invention;

FIG. 5 a schematic illustration of a detail of a top view of a solar cell according to FIG. 2. FIG. 2 shows here a cross-section along a line A in FIG. 5 and perpendicular in reference to the drawing plane in FIG. 5, and

FIG. 6 a schematic illustration of a detail of a rear view of a solar cell according to FIG. 4.

### DETAILED DESCRIPTION OF THE PREFERRED EMBODIMENTS

Identical reference characters mark identical elements in the figures.

In order to illustrate the general functionality of a bypass diode during the generation of a diode-like semiconductor contact the applicant performed the following experiments:

Argentiferous serigraphy pastes with various lead oxide concentrations were used for the production of a metallic contacting structure. The contacting structures were applied on a silicon substrate with a p-base doping ranging from 5×10¹⁵ cm⁻³ to 1.5×10¹⁶ cm⁻³.

Here, typical processing steps known per se for applying a metallic contacting structure via argentiferous serigraphy paste were used in silicon solar cells, such as for example described in “Sonnenenergie: Photovoltaik” (Solar energy: photo-voltaic) by Goetzberger, Voβ, Knobloch, 2^{nd} Edition, Teubner-Verlag Stuttgart and/or U.S. Pat. No. 4,235,644.

The method comprises the following processing steps: removing the serration at the surface of the p-type wafer by way of etching using caustic potash solution, applying a SiNx-layer via PECVD (plasma enhanced chemical vapor deposition) on the side to be printed with silver at a port of the wafer, printing by way of serigraphy using the Ag-paste (such as a typical front side contacting grid), printing via serigraphy using an Al-paste on the opposite side (to form an ohmic contact (and contact-flashing for a few seconds at 800° C.; subsequently measuring the parameters with an industrial cell tester.

The curve a) shows the current-voltage parameter of an experimental structure in which an argentiferous paste was used with a lead oxide content of less than 1%. The paste was applied directly on the semiconductor surface and the desired diode-like behavior already shows after the contact-flashing.

During operation in the forward direction (positive voltage values) the structure only exhibits a very low electric current flowing up to a voltage of approx. 0.8 V. This means that particularly in the relevant voltage range from 0 V to 0.6 V the structure can be called electrically blocking. In this voltage range the electric current flowing exhibits an electric flow rate below 10 mA/cm².

When a voltage is applied in the blocking direction, for example as is the case in a partial shadowing of a solar cell, a considerable electric current flow shows starting at voltages of less than −4.5 V (i.e. negative voltages with a value exceeding 4.5 V).

Although the structure in the voltage range from 0 V to −4 V can be called electrically blocking; however this is irrelevant, because in the event of reverse voltages and particularly a partial shadowing of the solar cells in a string typically voltages are applied at the shadowed solar cells of less than −5 V (i.e. negative voltages with a value exceeding 5 V) in the blocking direction.

This test structure therefore already shows the functionality of a bypass diode by it acting in the forward direction in an electrically blocking fashion in the relevant voltage range and in the reverse direction, at least at voltages below −4.5 V, in an electrically conductive fashion, so that a controlled breakdown is achieved in the blocking direction and particularly hot-spots are prevented.

The power voltage parameter marked b) shows a test structure with here the argentiferous paste comprising lead oxide at a content exceeding 2.5%. However this structure also shows the functionality of a bypass diode in case of voltages applied in the blocking direction (negative voltages). In voltages in the forward direction (positive voltages) this structure shows particularly in the relevant voltage range 0 V to 0.6 V a linear, i.e. almost ohmic progression, though. Therefore when a voltage is applied in the forward direction this structure cannot be called electrically blocking and thus fails to exhibit the desired functionality of a bypass diode. In an experimental fashion this confirms the above-stated preferred embodiment with an upper limit for the content of frit in the paste when producing the contacting structure.

The current-voltage parameter marked c) shows the measurement of a test structure, in which similar to the first test structure, lead oxide is contained at a rate of less than 1%. Additionally, in this test structure an electrically insulating silicon nitride layer is arranged here between the semiconductor and the argentiferous serigraphy paste showing a thickness of 80 nm. This way a metal-insulator semiconductor contact forms. Here, the metallization punctually penetrates the insulating silicon nitride layer so that, in spite of the presence of the silicon nitride layer, a metal-semiconductor contact with a diode-character forms.

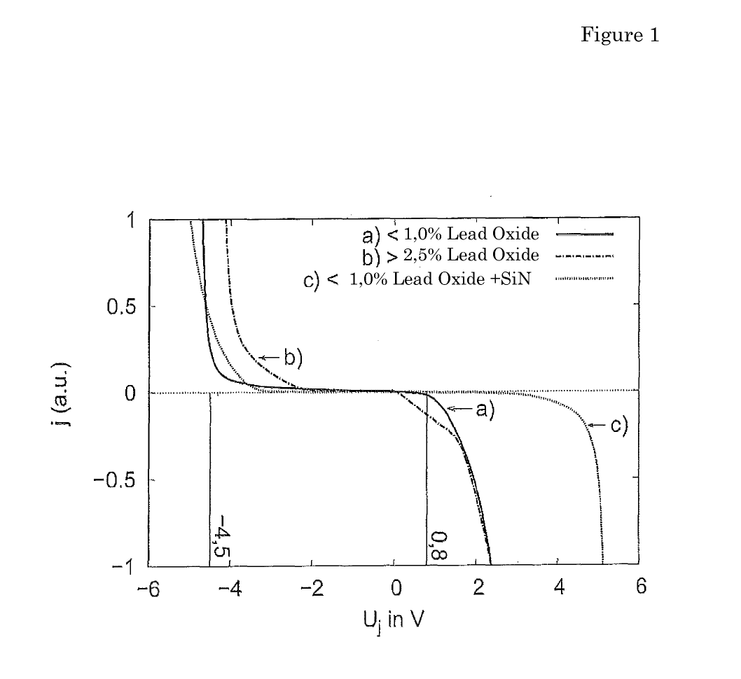

As discernible from FIG. 1 this structure shows the advantage that particularly in voltages applied in the forward direction (positive voltage values) considerably better blocking effects are yielded. Furthermore when voltage is applied in the blocking direction (negative voltage values) considerable electric current flows earlier, i.e. already at voltages of approx. −3.5 V, compared to the current-voltage parameter a).

Based on the present concentration of surface doping for the test structure therefore a metal-semiconductor contact develops with a desired diode-like character. In an identical processing step, when higher surface doping is given at the surface of the semiconductor with otherwise identical parameters, ohmic contacts may be generated, particularly for contacting an emitter or a base region. The embodiment of the ohmic contact is caused, unlike the above-mentioned test structure, particularly in the higher concentration of doping material (n or p doping material) at the surface of the semiconductor facing the metallization.

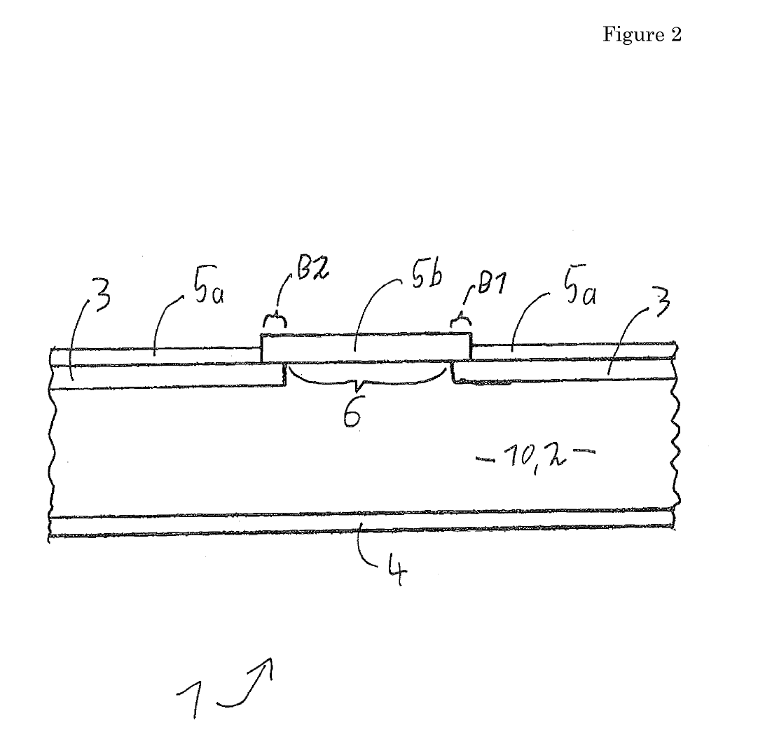

FIG. 2 shows schematically a detail of a first exemplary embodiment of a solar cell 1 according to the invention in a simplified illustration. The solar cells shown in FIGS. 2 to 4 respectively continue towards the right and the left.

The solar cell 1 according to FIG. 2 is produced from a silicon substrate 1 using multi-crystalline silicon. The silicon substrate 1 is p-doped and represents the base 2 of the solar cell.

At the front of the solar cell 1, during the operation of the solar cell facing the incident light in FIG. 2 shown on the top, sectionally an emitter 3 is already produced via diffusion of a n-doping substance, in this case phosphorus. The emitter is generated in a manner known per se and exhibits a layer resistance of 75 Ohm/square.

The rear of the solar cell is coated over its entire surface with a metallic base contacting structure 4, embodied as a metallic layer.

The frontal contacting of the emitter occurs in a manner known per se via a grid-like metallic contacting structure.

It is essential that the emitter contacting structure 5 is embodied in two parts.

During the diffusion of the emitter 3 in an overlapping region 6 the diffusion of the emitter was avoided. This was yielded such that prior to the diffusion in this region a silicon oxide layer was applied as a diffusion barrier.

Accordingly at the front of the silicon substrate 10 no emitter is present in the overlapping region 6, instead in said overlapping region a semiconductor is present with the p-doping of the base 2.

The emitter contacting structure 5 was generated in two parts: in a first partial region 5a an emitter contacting structure was applied in a manner known per se via serigraphy in the form of an argentiferous serigraphy paste for contacting the emitter 3.

Additionally, a partial region 5b of the emitter contacting structure was generated by applying an argentiferous serigraphy paste with a reduced lead oxide concentration.

Therefore, in a contact-flashing step on the one side an electric contact is generated between the partial region 5a of the emitter contacting structure 5 and the emitter 3, additionally a diode-like metal-semiconductor contact is generated between the partial region 5b of the emitter contacting structure and the base 2 in the overlapping region 6. This diode-like semiconductor contact exhibits a diode parameter according to the parameter a) in FIG. 1.

This way, by only a minor expansion of the production process, a solar cell has been produced which additionally shows the functionality of a bypass diode due to the diode-like semiconductor contacts in the overlapping region 6.

When the emitter contacting structure is embodied in several parts, as for example shown in FIG. 2, it is advantageous that those partial regions of the emitter contacting structure covering the overlapping region at least slightly project into the regions abutting the overlapping region 6. In the first exemplary embodiment shown in FIG. 2, the partial region 5b of the structure 5 contacting the emitter covers the emitter 3 in the regions B1 and B2. This has the following background:

Due to the composition of the partial region 5a of the emitter contacting structure 5 there would be a high risk that an ohmic contact develops between the emitter contacting structure and the base and thus a shunt (i.e. a short circuit with an ohmic character) when the partial region 5a of the emitter contacting structure 5 was directly covering a p-doped base region, such as the overlapping region 6.

By an at least slight covering of the emitter 3 at the boundary regions by the partial region 5b of the emitter contacting structure 4 the risk of such a formation of a shunt is reduced, which otherwise might lead to considerable loss in effectiveness; here a shunt formation is nearly excluded in this region.

Preferably the width of the overlapping regions B1 and B2 amounts to at least 50 μm.

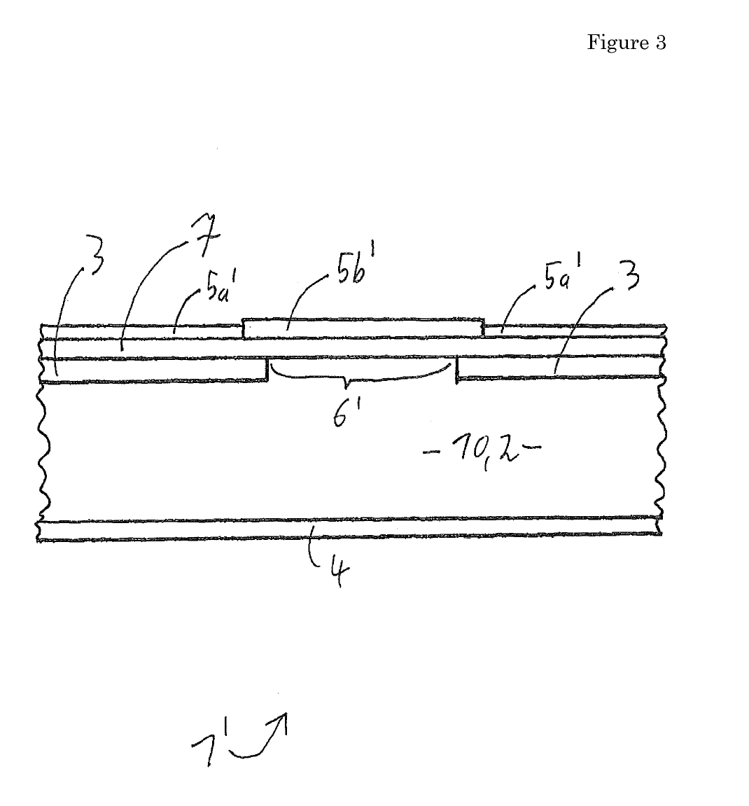

FIG. 3 shows a second exemplary embodiment of a solar cell 1′ according to the invention.

The design is similar to the design of the first exemplary embodiment according to FIG. 2 with regards to silicon substrate 10, base 2, emitter 3, and base contacting structure 4.

The embodiment of the diode-like semiconductor contact was realized in this second exemplary embodiment such that at the front, in a common fashion, the emitter contacting was formed by applying metallization fingers, which metallization fingers are connected via a bus bar as known per se. In this second exemplary embodiment the overlapping region 6′ was formed located underneath the bus bar 5b′. The bus bar was generated via an argentiferous serigraphy paste. First, in a manner known per se, an anti-reflection layer 7 embodied as a silicon nitride layer was applied with a thickness of 80 nm over the entire surface on the front of the silicon substrate 10. After contact-flashing here a metal semiconductor contact forms in the overlapping region 6′, which exhibits a current-voltage parameter according to the parameter c) in FIG. 1. As described above, during contact flashing, in spite of the presence of the anti-reflex layer 7, a metal-semiconductor contact forms with a diode character in the overlapping region 6′ because the metal partially (particularly punctually) penetrates the anti-reflection layer 7 during the contact-flashing.

Furthermore, the anti-reflection layer 7 acts in a reflection-reducing fashion with regards to the incident light at the front of the solar cell 1, located on top in FIG. 3, so that additionally light coupling is increased.

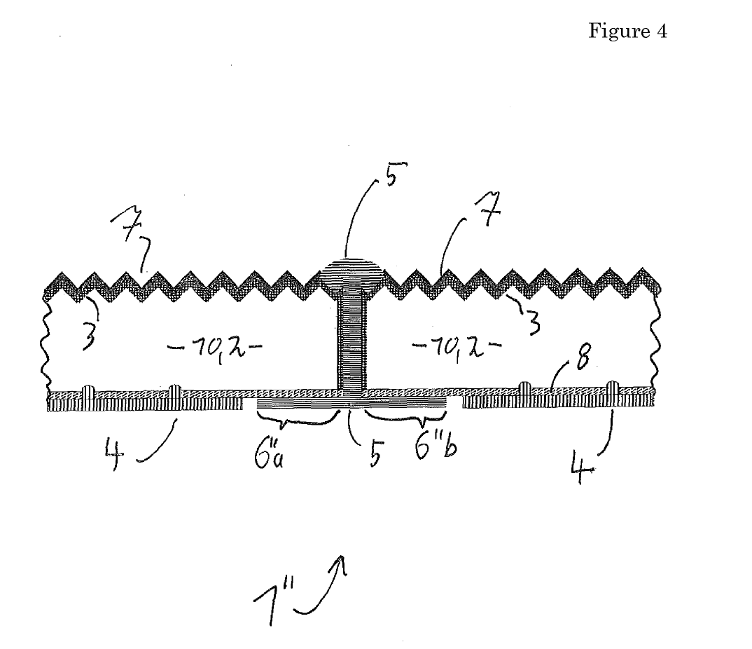

FIG. 4 shows a third exemplary embodiment of a solar cell 1″ according to the invention, also as a detail in a schematic illustration. The solar cell is based on the known MWT-solar cell structure, as described for example in U.S. Pat. No. 6,384,317 B1.

In such a solar cell structure the emitter contacting structure 5 is guided from the front via recesses in the solar cell to the rear such that at the rear both the emitter contacting structure 5 as well as the base contacting structure 4 can be contacted. The MWT-solar cell is therefore a unilaterally contacted solar cell.

A pyramidal structuring as well as an anti-reflection layer 7 is formed at the front to increase the light coupling of the front of the solar cell, located on top in FIG. 4. Additionally, an emitter 3 is embodied at the front of the solar cell 1″.

At the rear of the silicon substrate 10, which is also p-doped for the embodiment of the base 2, a layer system comprising aluminum oxide and silicon nitride 8 are applied over the entire surface.

This layer system is penetrated punctually in the areas of the base contacting structure 4 via the LFC-methods known per se (as described in U.S. Pat. No. 6,982,218 and/or WO 02/25742) so that in this limited points local electric contacts are formed between a base contacting structure 4 and a base 2.

It is essential that in the overlapping regions 6″a and 6″b a diode-like metal-semiconductor contact is established between the emitter contacting structure 5 and the base 2.

In the MWT-structure known per se, also with only minor adjustments of the production process, a MWT-solar cell can be produced, which additionally shows the functionality of a bypass diode.

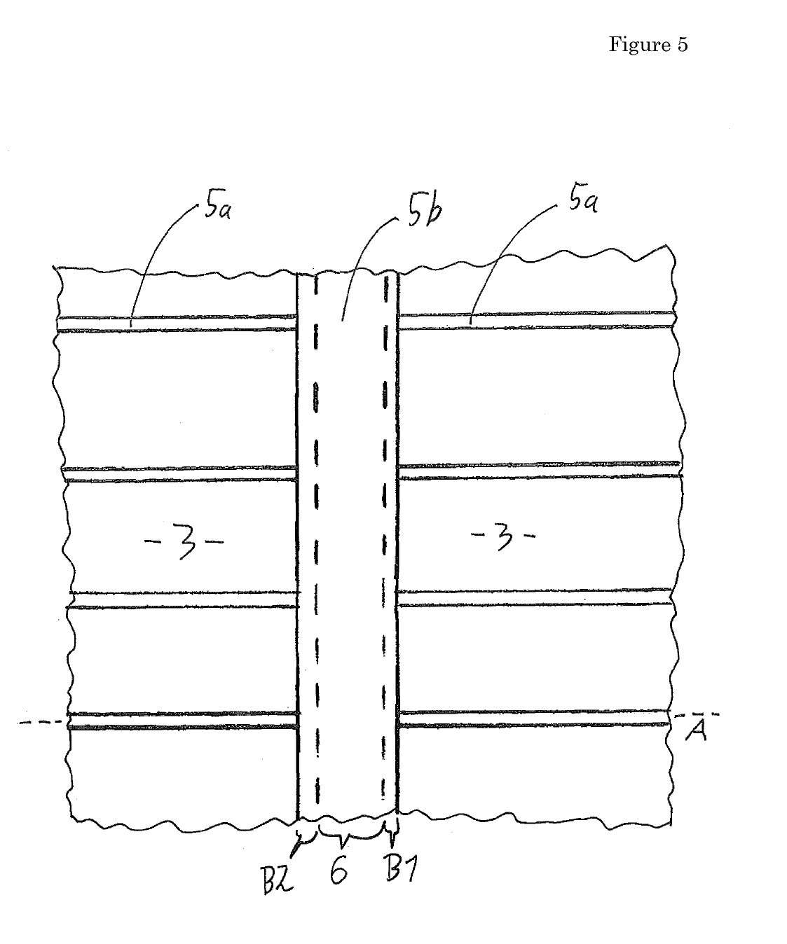

FIG. 5 shows a top view onto a solar cell according to FIG. 2, with FIG. 5 also showing a detail and a schematic illustration.

It is discernible from FIG. 5 that the front of the solar cell exhibits a double-chamber contacting grid in a form known per se, which comprises the partial region 5a embodied as contacting fingers and the partial section 5b embodied as the bus bar. The bus bar 5b entirely covers the overlapping region 6 and thus additionally covers the emitter section 3 of the solar cell in the regions B1 and B2.

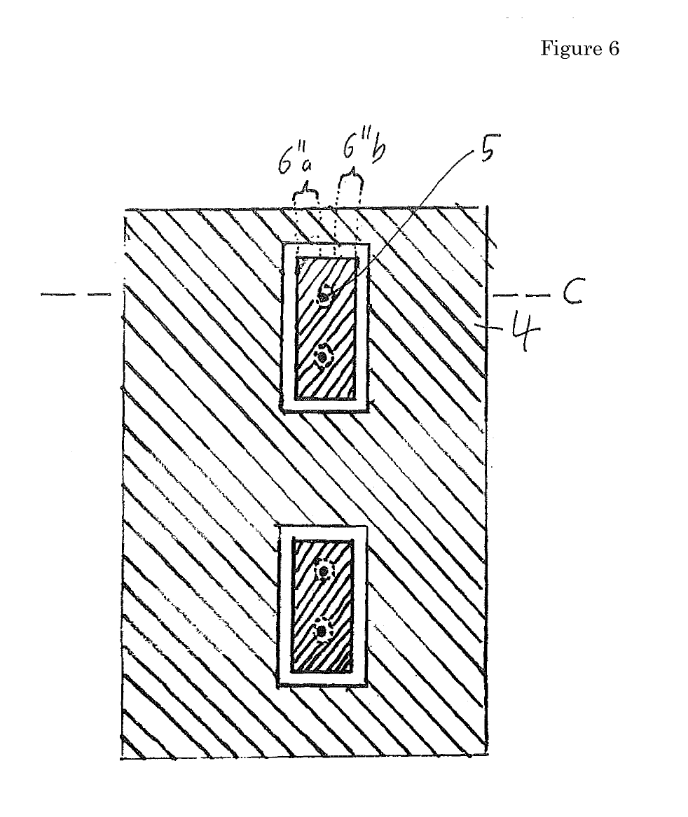

FIG. 6 shows a rear view of a solar cell according to FIG. 4. FIG. 6 also shows a detail and a schematic illustration.

FIG. 4 is a cross-sectional illustration according to a line C and perpendicular in reference to the drawing plane in FIG. 6.

As discernible from FIG. 6 and as common in MWT-solar cells the rear is essentially covered by the base metallization contacting structure 4. The emitter contacting structure 5 is arranged in isolated recesses, in which for a better understanding additionally the metallization is marked in the hole-like recesses. Furthermore, in FIG. 6 the overlapping regions 6″a and 6″b are shown according to FIG. 4.

1. A photovoltaic solar cell (1, 1′, 1″) for converting incident electromagnetic radiation into electric energy, comprising
at least one base region of a base doping type embodied in a silicon substrate (10),
at least one emitter region of an emitter doping type, said emitter doping type being a doping type opposite the base doping type,
at least one metallic base contacting structure (4), said base contacting structure (4) being connected to the base region in an electrically conducting fashion, and
at least one metallic emitter contacting structure (5), said emitter contacting structure (5) being connected to the emitter region in an electrically conductive fashion,
the base region and the emitter region being arranged such that between the base region and the emitter region at least sectionally a pn-junction forms, and
at least one of
(a) in a base bypass region the base contacting structure (4) overlaps the emitter region in an overlapping region (6, 6′, 6″a, and 6″b) which at least in a partial region thereof a diode-like semiconductor contact is formed between the base contacting structure (3) and the emitter region, said semiconductor contact being embodied as a metal-semiconductor contact or
(b) in an emitter bypass region the emitter contacting structure (5) overlaps the base region in an overlapping region (6, 6′, 6″a, and 6″b) at least in a partial region thereof a diode-like semiconductor contact is formed between the emitter contacting structure (5) and the base region, said semiconductor contact being embodied as a metal-semiconductor contact.

2. A solar cell (1, 1′, 1″) according to claim 1, wherein one or more of the diode-like semiconductor contacts in one or more of the overlapping regions (6, 6′, 6″a, and 6″b) is embodied at least when a reverse voltage is applied at the metallic contact structures with an amount greater than 5 V, electrically conducting in a reverse direction with an electric flow rate greater than 100 mA/cm².

3. A solar cell (1, 1′, 1″) according to claim 1, wherein the diode-like semiconductor contact is embodied in an electrically blocking fashion when a forward voltage is applied to the metallic contact structure ranging from 0 V to 0.5 V, with a flow rate in this voltage range embodied below 100 mA/cm².

4. A solar cell (1, 1′, 1″) according to claim 1, wherein one or more of the overlapping regions are formed and an overall area of the overlapping region or regions exceed 0.5%, of the overall area of the solar cell (1, 1′, 1″).

5. A solar cell (1, 1′, 1″) according to claim 1, wherein a partial region of one or more of the overlapping regions (6, 6′, 6″a, and 6″b) a diode-like metal-insulator semiconductor contact is formed by an insulating layer arranged between the metallic contacting structure and the semiconductor, said insulating layer preferably having at least one of a thickness of less than 200 nm or a thickness greater than 1 nm.

6. A solar cell (1, 1′, 1″) according to claim 1, wherein at least in one or more of the overlapping regions (6, 6′, 6″a, 6″b) the metallic contact structure has a glass frit content of less than 5 or no glass frit.

7. A solar cell (1, 1′, 1″) according to claim 1, wherein in one or more of the overlapping regions (6, 6′, 6″a, 6″b) a concentration of doping substance in the semiconductor at a surface facing the metallic contacting structure is below 10¹⁹ cm⁻³.

8. A solar cell (1, 1′, 1″) according to claim 1, wherein at least one of in a base bypass region, the base contacting structure (4) comprises one or more metals of the group consisting of: silver, aluminum, titanium, palladium, zinc, platinum, nickel, tin, lead, cobalt, tungsten, and bismuth, or in the emitter bypass region the emitter contacting structure (5) comprises one or more metals of the group consisting of: silver, aluminum, titanium, palladium, zinc, platinum, nickel, tin, lead, cobalt, tungsten, and bismuth.

9. A solar cell (1, 1′, 1″) according to claim 1, wherein in one or more of the overlapping regions (6, 6′, 6″a, 6″b) the diode-like metal-semiconductor contact or diode-like metal-insulator semiconductor contact is embodied with a diode located in a direction of flow when a forward voltage is applied at one of the metallic contact structures.

10. A solar cell (1, 1′, 1″) according to claim 1, wherein at least in one or more of the overlapping regions (6, 6′, 6″a, 6″b) the contacting structure is embodied as a laminate system, with at least one interim layer being formed between the semiconductor and a metallic layer in order to improve the electric insulating effect in the one or more overlapping regions (6, 6′, 6″a, 6″b) when a voltage is applied in the forward direction.

11. A solar cell (1, 1′, 1″) according to claim 1, wherein the semiconductor surface is planar at least in one or more of the overlapping regions (6, 6′, 6″a, 6″b).

12. A solar cell (1, 1′, 1″) according to claim 1, wherein the solar cell is a MWT-solar cell, which has at least one metallic penetrating contact from a front side to a rear side of the solar cell and one or more of the overlapping regions (6″a, 6″b) is embodied at the rear and a diode-like semiconductor contact is formed between the emitter contacting structure (5) and the base section, said semiconductor contact is embodied as a metal-semiconductor contact.

13. A solar cell module, comprising one or more solar cells according to claim 1, wherein said solar cells are electrically connected to each other in at least one of serial or parallel circuits, with the solar cell module not comprising any bypass diode, except for the integral diode-like semiconductor contact or contacts of the solar cells.

14. A method for the production of a photovoltaic solar cell (1, 1′, 1″) comprising the following processing steps
providing a silicon substrate with a base section of a base doping type embodied in said silicon substrate,
forming an emitter region in or at the silicon substrate (10), said emitter region being embodied with an emitter doping type opposite the base doping type, so that between the base region and the emitter region at least sectionally a pn-junction forms,
applying a metallic base contacting structure (4), said base contacting structure (4) is connected to the base section in an electrically conductive fashion, and
applying at least one metallic emitter contacting structure (8), said emitter contacting structure (5) is connected to the emitter region in an electrically conductive fashion, and
at least one of
(a) in a base bypass region applying the base contacting structure (4) overlapping the emitter region in an overlapping region (6, 6′, 6″a, and 6″b), and forming a diode-like metal semiconductor contact between the base contacting structure (4) and the emitter region in the overlapping region or
(b) in an emitter bypass region applying the emitter contacting structure (5) overlapping the base region in an overlapping region (6, 6′, 6″a, and 6″b), and forming a diode-like metal semiconductor contact between the emitter contacting structure (5) and the base region in the overlapping region.

15. A method according to claim 14, wherein at least in partial sections of one or more of the overlapping regions (6, 6′, 6″a, 6″b) the contacting structure is applied via serigraphy.

16. A method according to claim 14, wherein at least in areas of one or more of the overlapping regions (6, 6′, 6″a, 6″b) the contacting structure is generated via non-contacting printing methods.

17. A method according to claim 15, wherein metal paste that is applied comprises frit at a rate from 0.1% to 2%.

18. A method according to claim 17, wherein the metal paste comprises one or more oxides.

19. A method according to claim 14, wherein at least in regions of one or more of the overlapping region (6, 6′, 6″a, 6″b) the contacting structure is generated via physical gas phase precipitation.

20. A method according to claim 14, wherein after the application of the contacting structure in one or more of the overlapping regions (6, 6′, 6″a, 6″b) a contact flashing step is performed.

21. A method according to claim 14, wherein the emitter (3) is formed via diffusion in a silicon substrate (10), and in the overlapping region (6, 6′, 6″a, 6″b) a diode-like semiconductor contact is formed between the contacting structure and the base region, with during the diffusion of the emitter in the overlapping region (6, 6′, 6″a, 6″b) via masking a diffusion is prevented or that after the diffusion of the emitter in the overlapping region (6, 6′, 6″a, 6″b) the emitter (3) is removed.

22. A method according to claim 14, wherein the solar cell is embodied as a MWT-solar cell, with at least one metallic penetrating contact being formed from a front side to a rear of the solar cell, and one or more of the overlapping regions (6″a, 6″b) is formed at the rear and a diode-like semiconductor contact is formed in a partial section of the overlapping region between the emitter contacting structure (5) and the base section, said semiconductor contact is embodied as a metal semiconductor contact.
